(19) United States
(12) Patent Application Publication
(10) Pub. No.: US 2017/0127544 A1
(43) Pub. Date: May 4, 2017

(54) Displaying Device

(71) Applicant: Diode-On Optoelectronics Limited, Taichung City (TW)

(72) Inventor: Ivan Liu, Taichung City (TW)

(21) Appl. No.: 14/931,252

(22) Filed: Nov. 3, 2015

(51) Int. Cl. H05K 7/02

(52) U.S. Cl. CPC H05K 7/02

(57) ABSTRACT

A displaying unit includes a rail unit, a connecting unit and a display unit. The rail unit includes a rail that extends in a lengthwise direction, a fixed circuit board that is disposed in the rail and that extends in the lengthwise direction, and a fixed electrode set that is disposed fixedly on the fixed circuit board and that extends in the lengthwise direction. The connecting unit is slidable on the rail in the lengthwise direction and includes a movable electrode set that is in sliding contact with the fixed electrode set. The display unit is connected to the connecting unit and is electrically connected to the movable electrode set.

### FIELD

The disclosure relates to a displaying device, and more particularly to a displaying device having a rail unit.

### BACKGROUND

Instead of appointing staff standing beside display cabinets in stores or museums for providing relevant information about a product or exhibition in display, oftentimes, a displaying device, which includes audio visual setups and a plurality of electrical cables, is disposed adjacent to the display cabinets for providing such information, so that potential customers or visitors may obtain information about the product or exhibition. When the displaying device is flush mounted to a mounting surface, the electrical cables of the displaying device are embedded and concealed so as to create a neat visual appearance. However, it is troublesome to move such displaying device around. When the displaying device is secured using fastening components, the displaying device can be moved around and repositioned depending on location of the display cabinets. However, the electrical cables of the displaying device are not concealed and a relatively messy appearance may be perceived. Furthermore, when the displaying device is to be repositioned, the electrical cables of the displaying device may have to be re-routed, and the displaying device has to be disassembled and assembled again, which is relatively inconvenient and time consuming.

### SUMMARY

Therefore, an object of the disclosure is to provide a displaying device that can alleviate at least one of the drawbacks of the prior art.

According to the disclosure, the displaying device includes a rail unit, a connecting unit and a display unit. The rail unit includes a rail that extends in a lengthwise direction, a fixed circuit board that is disposed in the rail and that extends in the lengthwise direction, and a fixed electrode set that is disposed fixedly on the fixed circuit board and that extends in the lengthwise direction. The connecting unit is slidable on the rail in the lengthwise direction and includes a movable electrode set that is in sliding contact with the fixed electrode set. The display unit is connected to the connecting unit and is electrically connected to the movable electrode set.

### BRIEF DESCRIPTION OF THE DRAWINGS

Other features and advantages of the disclosure will become apparent in the following detailed description of the embodiments with reference to the accompanying drawings, of which:

FIG. 1 is a perspective view of a first embodiment of a displaying device according to the disclosure;

FIG. 2 is a partly exploded perspective view of the first embodiment;

FIG. 3 is a schematic partly sectional view of the first embodiment;

FIG. 4 is a fragmentary schematic view of the first embodiment, illustrating that a protruding block of a rotatable module does not contact a limiting protrusion of a slidable module;

FIG. 5 is a view similar to FIG. 4, illustrating that the protruding block contacts the limiting protrusion;

FIG. 6 is view similar to FIG. 3, illustrating how a display unit is assembled onto a rail unit;

FIG. 7 is a perspective view of a second embodiment of the displaying device according to the disclosure;

FIG. 8 is a partly exploded perspective view of the second embodiment;

FIG. 9 is a schematic partly sectional view of the second embodiment;

FIG. 10 is a fragmentary schematic view of the second embodiment, illustrating relative positions of a retaining ring of a rotatable module and a limiting protrusion of a slidable module;

FIG. 11 is a schematic partly sectional view illustrating a variation of a rail of the second embodiment; and

FIG. 12 is a view similar to FIG. 11, illustrating a variation of a fixed circuit board of the second embodiment.

### DETAILED DESCRIPTION

Before the disclosure is described in greater detail, it should be noted that like elements are denoted by the same reference numerals throughout the disclosure.

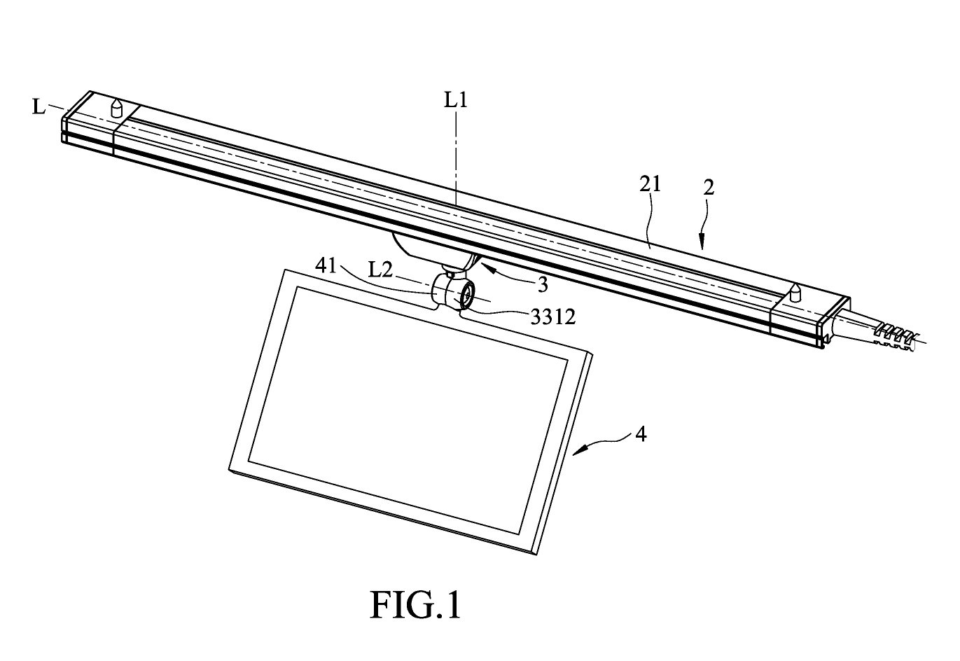

Referring to FIGS. 1 to 3, a first embodiment of a displaying device according to the disclosure includes a rail unit 2, a connecting unit 3 and a display unit 4.

The rail unit 2 includes a rail 21, a fixed circuit board 22 and a fixed electrode set 23. The rail 21 extends in a lengthwise direction (L). The rail 21 includes a connecting wall 211, two side walls 212, two mounting walls 215, two inner guiding flanges 214 and two outer guiding flanges 213.

The side walls 212 extend downwardly and respectively from two opposite sides of the connecting wall 211. The mounting walls 215 are located between the side walls 212, are spaced apart from each other, and extend respectively from intermediate portions of the side walls 212 toward each other. Each of the inner guiding flanges 214 extends downwardly from an end of a respective one of the mounting walls 215 which is distal from a corresponding one of the side walls 212. The outer guiding flanges 213 extend in the lengthwise direction (L) and are spaced apart from each other in a direction perpendicular to the lengthwise direction (L). The outer guiding flanges 213 respectively extend from bottom ends of the side walls 212 toward the inner guiding flanges 214 and are spaced apart from the inner guiding flanges 214. Each of the outer guiding flanges 213 cooperates with a respective one of the inner guiding flanges 214, a corresponding one of the side walls 212, and the respective one of the mounting walls 215 to define a guiding groove 210 thereamong so that the guiding groove 210 has a lower opening 216. Note that the configurations of the mounting walls 215 may be varied in other embodiments of this disclosure and is not limited to the aspect disclosed herein.

The fixed circuit board 22 is disposed between the inner guiding flanges 214 of the rail 21, and extends in the lengthwise direction (L).

The fixed electrode set 23 is fixedly disposed on the fixed circuit board 22, and includes two spaced-apart fixed electrodes 230 extending in the lengthwise direction (L).

In this embodiment, the rail 21 is formed integrally by, but not limited to, aluminum extrusion. The fixed electrodes 230 are made of metal and are connected to a power supply (not shown) via a transformer (not shown). One of the fixed electrodes 230 is a positive electrode, and the other one of the fixed electrodes 230 is a negative electrode.

The connecting unit 3 is slidable on the rail 21 in the lengthwise direction (L). The connecting unit 3 includes a slidable module 31 that is detachably and sliadably mounted to the outer guiding flanges 213 of the rail 21, a rotatable module 33 that interconnects the slidable module 31 and the display unit 4, and a retaining module 32.

The slidable module 31 includes a housing 311, a mounting seat 312, a slidable circuit board 313 and a movable electrode set 314.

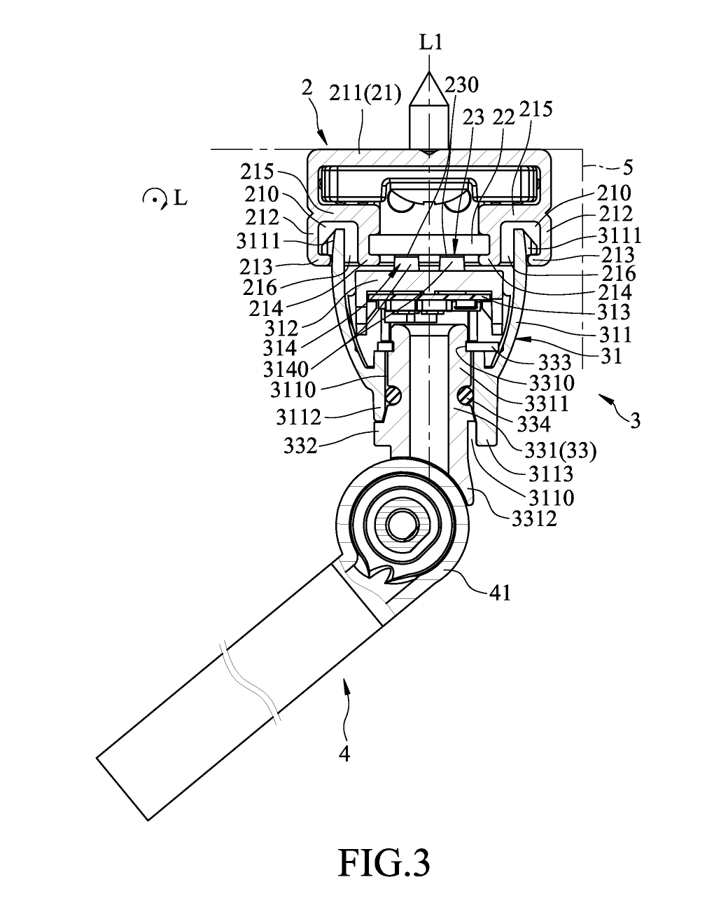

The housing 311 permits the display unit 4 to be rotatably mounted thereto via the rotatable module 33, and includes a tubular wall 3112 and a limiting protrusion 3113 (see FIG. 3). The tubular wall 3112 is located at a bottom end of the housing 311, surrounds a first axis (L1) that is perpendicular to the rail 21, and defines a through hole 3110. The limiting protrusion 3113 extends downwardly from a bottom end of the tubular wall 3112. The housing 311 is configured with two pairs of hooks 3111 disposed respectively at two ends of the housing 311 that are opposite to each other in the lengthwise direction (L). For each pair of the hooks 3111, each hook 3111 is inserted into a respective one of the guiding grooves 210 through a corresponding one of the lower openings 216, and detachably and slidably engages a corresponding one of the outer guiding flanges 213. Alternatively, in other variations of the embodiment, the number of the hooks 3111 of the housing 311 may be two, six, and etc. with no particular restriction.

The mounting seat 312 is disposed in the housing 311. The slidable circuit board 313 is disposed on the mounting seat 312 and permits the movable electrode set 314 to be disposed on. The movable electrode set 314 includes two spaced-apart movable electrodes 3140 in sliding contact with the fixed electrodes 230, respectively.

In this embodiment, the slidable module 31 further includes a bridge rectifier (not shown) that is electrically connected to the movable electrodes 3140 so that the slidable module 31 can be mounted to the rail unit 2 without concerning electrical polarities of the movable electrodes 3140 and the fixed electrodes 230.

The rotatable module 33 of the connecting unit 3 includes a rotatable shaft 331, a protruding block 332, a C-shaped retaining ring 333 and an O-ring 334.

The rotatable shaft 331 is inserted into the tubular wall 3112 of the housing 311 through the through hole 3110, and is rotatable about the first axis (L1). The rotatable shaft 331 includes a tubular portion 3311 that is partially inserted into the through hole 3110 of the housing 311, and a pivot portion 3312 that permits the display unit 4 to be pivotally connected thereto. The tubular portion 3311 has an outer surface formed with an annular groove 3310 (see FIG. 3).

The protruding block 332 extends outwardly from an outer surface of the rotatable shaft 331 and is co-rotatable with the rotatable shaft 331 to contact the limiting protrusion 3113 of the housing 311 so as to limit rotation of the rotatable shaft 331.

The C-shaped retaining ring 333 engages the annular groove 3310 of the tubular portion 3311 of the rotatable shaft 331, and abuts against a top end of the tubular wall 3112 of the housing 311 for preventing removal of the tubular portion 3311 from the through hole 3110.

The O-ring 334 is sleeved on the tubular portion 3311 of the rotatable shaft 331, and is in frictional contact with an inner surface of the tubular wall 3112 so as to prevent rotation of the display unit 4 caused by an external impact force exerted on the display unit 4.

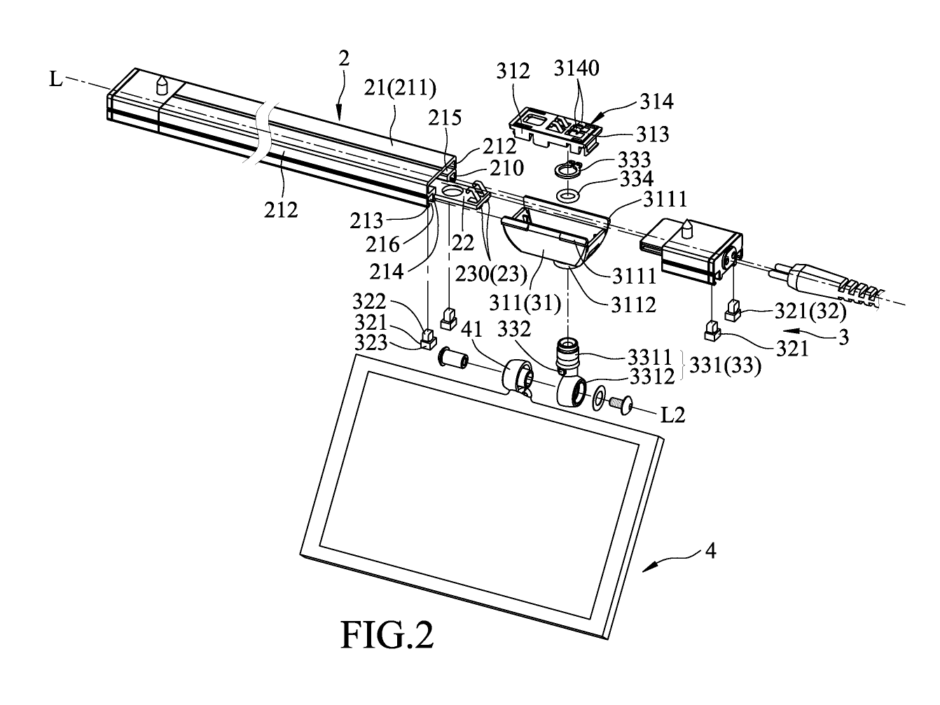

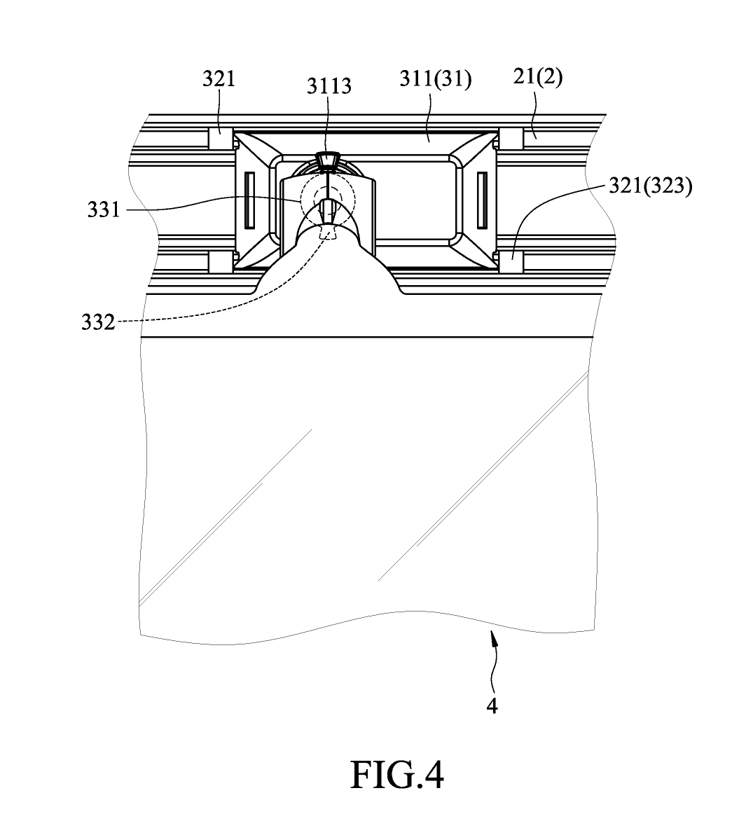

Referring to FIGS. 2 and 4, the retaining module 32 of the connecting unit 3 has two pairs of retaining pieces 321 that are spaced apart in the lengthwise direction (L), and that are removably inserted into the lower openings 216 of the guiding grooves 210. For each pair of the retaining pieces 321, each retaining piece 321 blocks a corresponding one of the hooks 3111 in the lengthwise direction (L) so as to prevent movement of the housing 311 of the slidable module 31 relative to the rail 21 and has an insert portion 322 inserted into a corresponding one of the lower openings 216 of the guiding grooves 210, and a hold portion 323 protruding out of the corresponding one of the lower openings 216. In this embodiment, the number of the retaining pieces 321 is four, but in other variations of this embodiment, the retaining module 32 may have only two retaining pieces 321 that are removably inserted into one of the lower openings 216 of the guiding grooves 210, and each of the retaining pieces 321 blocks one of the hooks 3111, which is inserted into said one of the lower openings 216, in the lengthwise direction (L). In other examples, as long as the retaining module 32 is capable of preventing movement of the housing 311 relative to the rail 21 in the lengthwise direction (L), the structure of the retaining module 32 is not limited to that provided in this embodiment.

The display unit 4 is electrically connected to the movable electrode set 314. The display unit 4 has a pivot portion 41 that is pivotally connected to the pivot portion 3312 of the rotatable shaft 331, such that the display unit 4 is pivotable relative to the pivot portion 3312 of the rotatable shaft 331 about a second axis (L2) that is perpendicular to the first axis (L1). In this embodiment, the display unit 4 is a monitor that has a display size smaller than 13 inches. Alternatively, in other variations of the embodiment, the display unit 4 may be a combination of a monitor and a speaker.

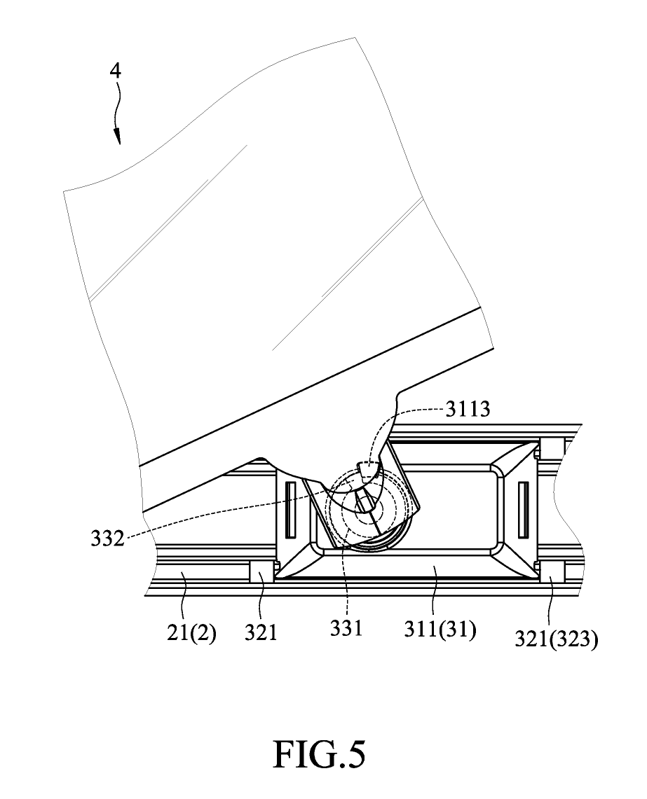

Referring to FIGS. 4 to 5, when the display unit 4 is rotated manually about the first axis (L1), the rotatable shaft 331 of the rotatable module 33 co-rotates therewith. The limiting protrusion 3113 of the housing 311 arrests rotation of the rotatable shaft 331 when the protruding block 332 contacts and abuts against one of opposite side surfaces of the limiting protrusion 3113. Therefore, a maximum rotation angle of the rotatable shaft 331 about the first axis (L1) is limited by the angle formed between the opposite side surfaces of the limiting protrusion 3113. In this embodiment, the angle formed between the opposite side surfaces of the limiting protrusion 3113 is 60 degrees, so that the rotatable shaft 331 is rotatable between 0 degree and 300 degrees.

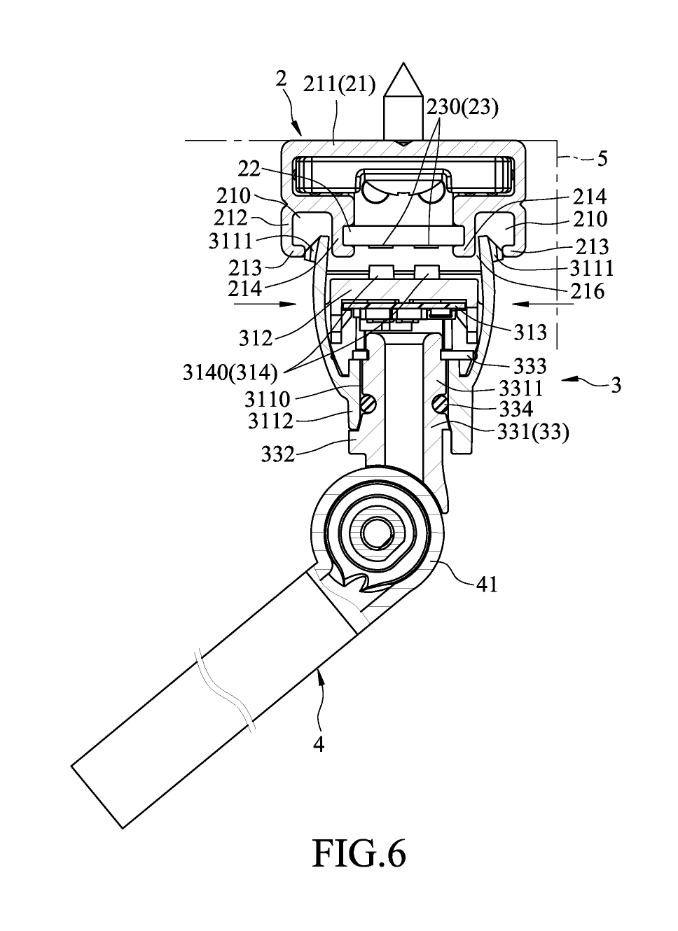

As shown in FIG. 6, to assemble the display unit 4 onto the rail unit 2, two opposite side surfaces of the housing 311 of the slidable module 31 are pressed inwardly as indicated by two arrows shown in FIG. 6 to bring the hooks 3111 of each pair of hooks 3111, which are located on the opposite side surfaces of the housing 311, to move toward each other. At this time, each pair of the hooks 3111 can be inserted respectively into the guiding grooves 210 through the corresponding lower openings 216, and then the side surfaces of the housing 311 are released to permit the hooks 3111 to engage the outer guiding flanges 213 of the rail 21, respectively. The configuration of the hooks 3111 provides a relatively easy assembly and alleviates possible obstruction due to the presence of a surrounding facility, such as a wall 5.

The position of the display unit 4 can be adjusted by sliding the housing 311 of the slidable module 31 along the rail 21 in the lengthwise direction (L), and an angle between the display unit 4 and the rotatable shaft 331 of the rotatable module 33 can be adjusted by pivoting the pivot portion 41 of the display unit 4 relative to the rotatable module 33 according to actual needs.

It should be noted that the rotatable module 33 of the connecting unit 3 may be omitted in this embodiment. That is, the display unit 4 may be directly and rotatably connected to the slidable module 31.

To sum up, the displaying device of the first embodiment of the disclosure has the following advantages:

1. Location of the display unit 4 can be adjusted based on actual needs. The position of the display unit 4 relative to the rail 21 is adjustable by sliding the housing 311 of the slidable module 31 along the lengthwise direction (L), and the angle between the display unit 4 and the rotatable shaft 331 is adjustable via pivot connection between the rotatable module 33 and the pivot portion 41 of the display unit 4. The retaining module 32 of the connecting unit 3 can be used to prevent movement of the display unit 4 along the rail 21 after adjustment.

2. By virtue of the configuration of the fixed electrode set 23 and the movable electrode set 314, an electrical cable for providing electricity to the display unit 4 is concealed, thus providing a relatively neat appearance.

3. Since the hooks 3111 of the housing 311 of the connecting unit 3 are disposed in the guiding grooves 210 of the rail 21, and the hooks 3111 are pressed inwardly instead of expanding outwardly for the assembly of the display unit 4 onto the rail 21, possible obstruction due to the presence of the wall 5 is alleviated.

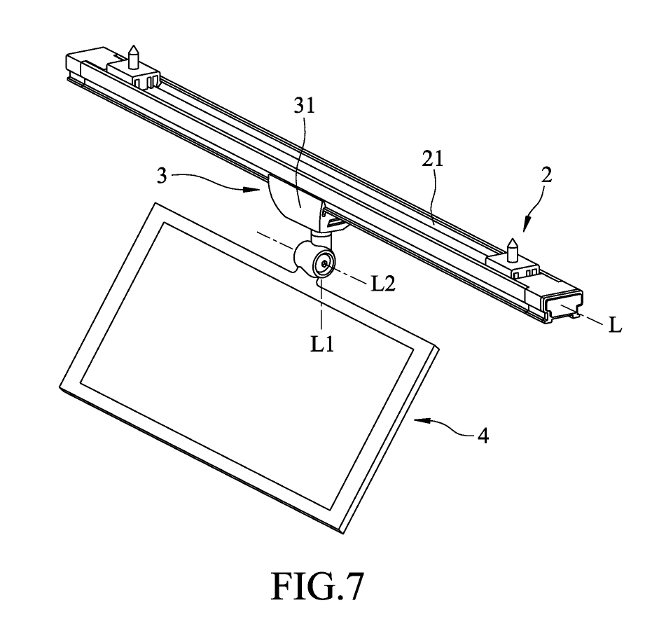

Referring to FIGS. 7 to 10, a second embodiment of the displaying device according to the disclosure is similar to the first embodiment. The difference between the first and second embodiments resides in the structures of the rail unit 2 and the connecting unit 3.

In this embodiment, the housing 311 of the slidable module 31 is configured with two hooks 3111. The mounting walls 215 (see FIG. 3) of the rail 21 are omitted. The connecting wall 211 of the rail 21 interconnects the side walls 212. Top ends of the side walls 212 are higher than a top surface of the connecting wall 211. The inner guiding flanges 214 extend respectively from bottom ends of the side walls 212 toward each other for placement of the fixed circuit board 22 thereon. Each of the outer guiding flanges 213 extends from the bottom end of a respective one of the side walls 212 away from each other. Each of the side walls 212 cooperates with the respective one of the outer guiding flanges 213 to define the guiding groove 210 that detachably and slidably engages a corresponding one of the hooks 3111 of the housing 311.

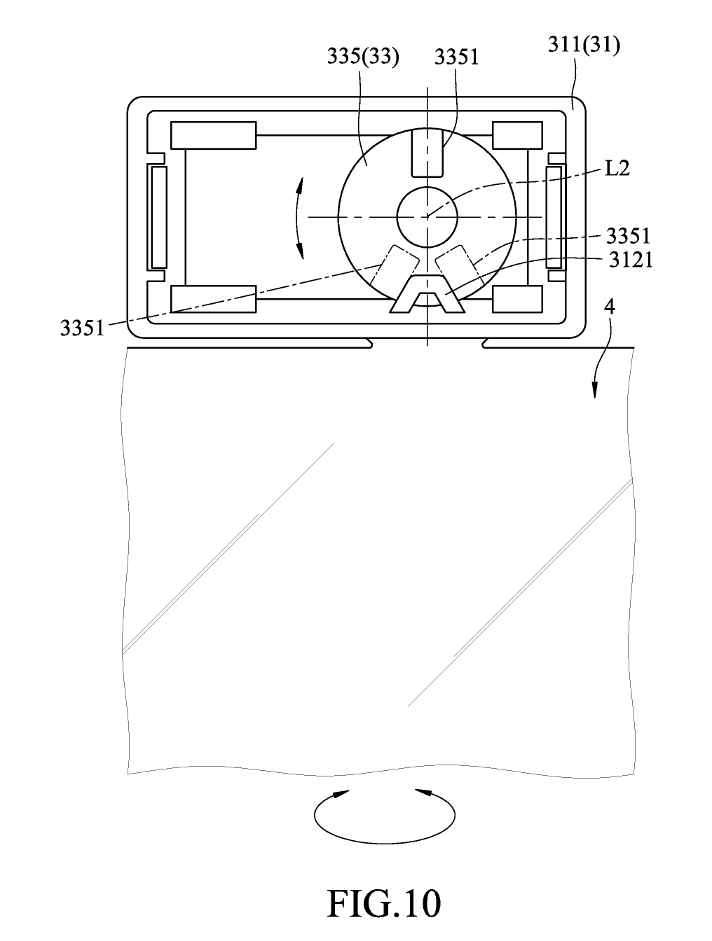

The through hole 3110 of the housing 311 is formed in a bottom wall of the housing 311. The mounting seat 312 has a limiting protrusion 3121 that extends downwardly toward the rotatable module 33, that is frusto V-shaped (see FIG. 10), and that serves the same purpose as the limiting protrusion 3113 (see FIG. 3) of the housing 311. In this embodiment, an angle formed between two opposite side surfaces of the limiting protrusion 3121 is 60 degrees.

In this embodiment, the C-shape retaining ring 333 (see FIG. 2) of the rotatable module 33 is omitted. The rotatable module 33 further includes a retaining ring 335. The rotatable shaft 331 is inserted into the through hole 3110, and has a threaded portion 3313 opposite to the pivot portion 3312. The retaining ring 335 is disposed under the mounting seat 312, is threadedly connected to the threaded portion 3313 of the rotatable shaft 331, and is co-rotatable with the rotatable shaft 331. The retaining ring 335 has a protruding portion 3351 extending upwardly toward the mounting seat 312 and rotatable to contact the limiting protrusion 3121 of the mounting seat 312 so as to limit rotation of the rotatable shaft 331. Specifically, as shown in FIG. 10, when the retaining ring 335 co-rotates with the rotatable shaft 331, the protruding portion 3351 of the retaining ring 335 rotates between positions indicated by phantom line. The O-ring 334 is disposed between the retaining ring 335 and adjacent to the bottom wall of the housing 311.

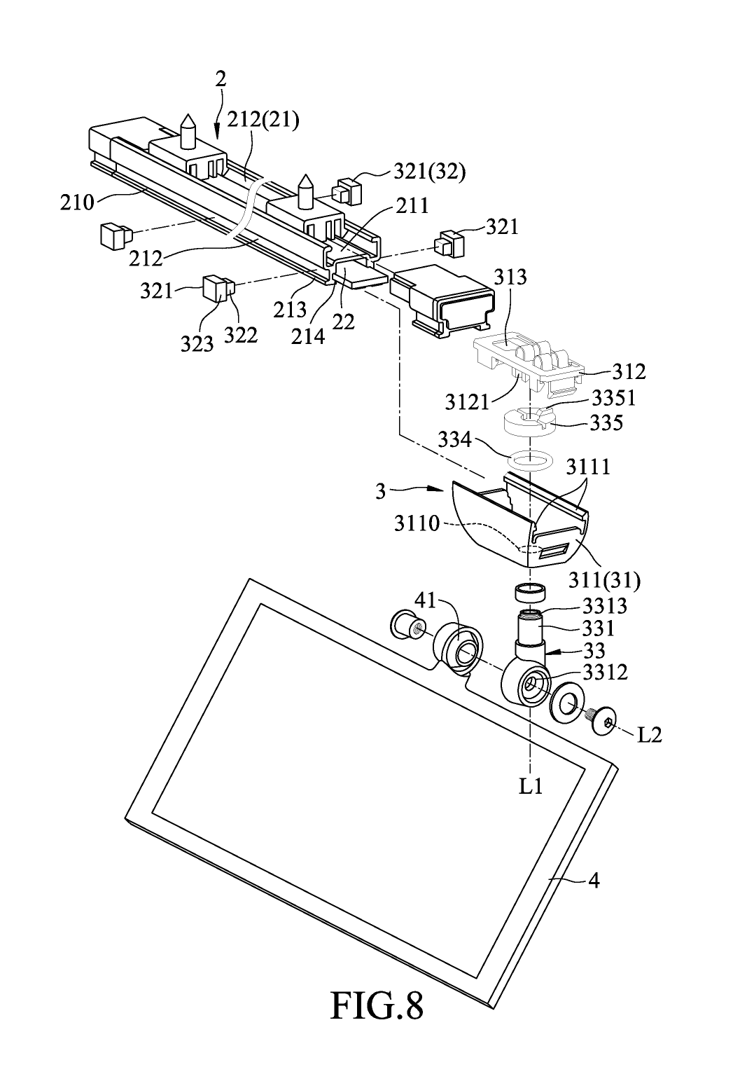

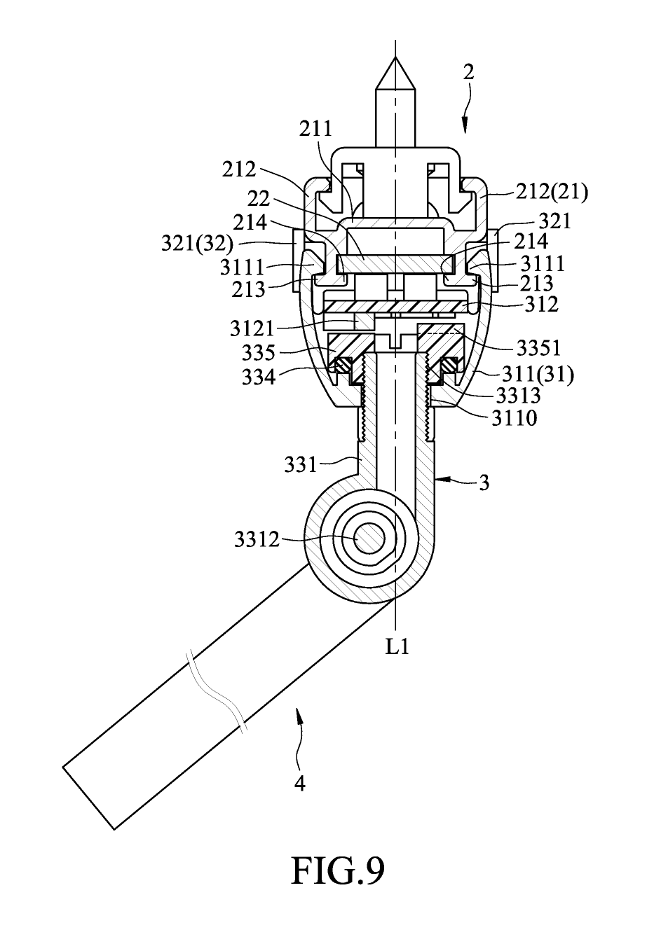

As shown in FIGS. 8 and 9, the insert portions 322 of retaining pieces 321 of the retaining module 32 are inserted into the guiding grooves 210, respectively. The hold portions 323 of retaining pieces 321 protrude out of the guiding grooves 210. The position of the display unit 4 relative to the rail 21 is adjustable by sliding the housing 311 of the slidable module 31 in the lengthwise direction (L), and an angle between the display unit 4 and the rotatable shaft 331 of the rotatable module 33 is adjustable via pivot connection between the rotatable module 33 and the pivot portion 41 of the display unit 4. Thus, the second embodiment can achieve the same function as that of the first embodiment.

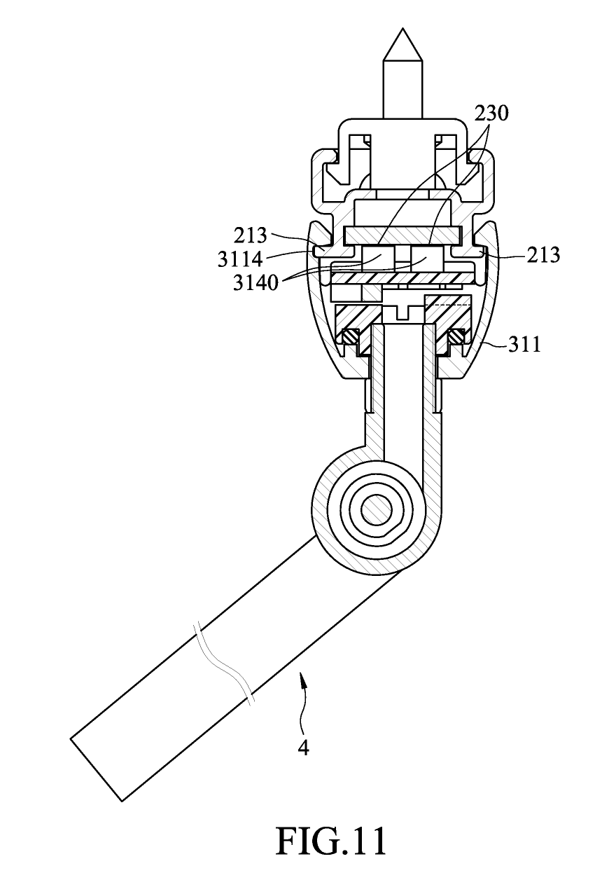

Referring to FIG. 11, in a variation of the second embodiment, one of the outer guiding flanges 213 has a width greater than that of the other one of the outer guiding flanges 213 in the direction perpendicular to the lengthwise direction (L). The housing 311 has an inner surface formed with a retaining groove 3114 that slidably engages said one of the outer guiding flanges 213, which has a greater width. Such configuration prevents misalignment between the movable electrodes 3140 and the fixed electrodes 230 when the slidable module 31 is mounted to the rail unit 2.

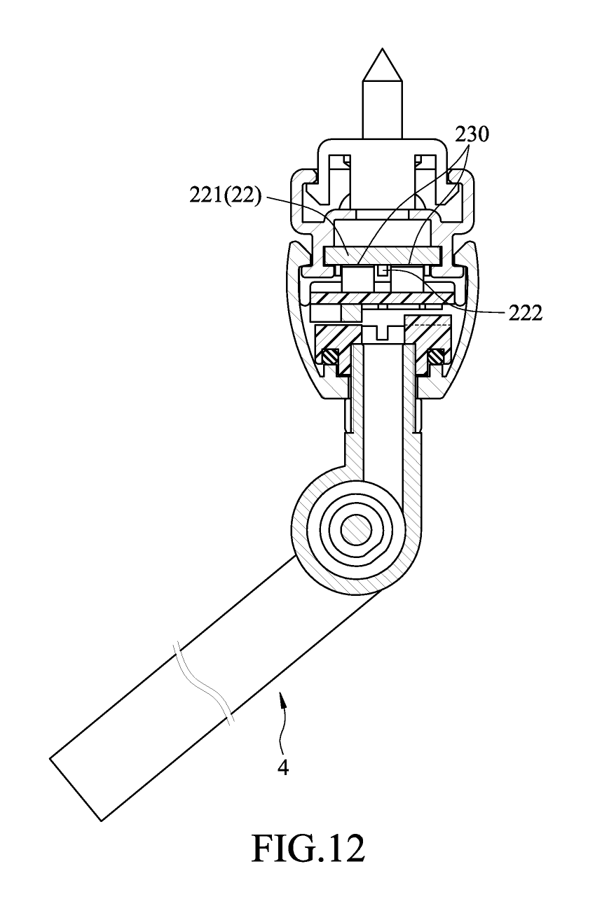

Referring to FIG. 12, in another variation of the second embodiment, the fixed circuit board 22 includes a board body 221, and a partition 222 disposed on the board body 221 and between the fixed electrodes 230 for separating the fixed electrodes 230, so as to prevent a short circuit that is caused by deformation and contact between the fixed electrodes 230 due to overheating.

While the disclosure has been described in connection with what are considered the exemplary embodiments and variations thereof, it is understood that this disclosure is not limited to the disclosed embodiments and variations thereof but is intended to cover various arrangements included within the spirit and scope of the broadest interpretation so as to encompass all such modifications and equivalent arrangements.

What is claimed is:

1. A displaying device comprising:
a rail unit including a rail that extends in a lengthwise direction, a fixed circuit board that is disposed in said rail and that extends in the lengthwise direction, and a fixed electrode set that is disposed fixedly on said fixed circuit board and that extends in the lengthwise direction;
a connecting unit slidable on said rail in the lengthwise direction and including a movable electrode set that is in sliding contact with said fixed electrode set; and
a display unit connected to said connecting unit and electrically connected to said movable electrode set.

2. The displaying device as claimed in claim 1, wherein said rail includes two outer guiding flanges extending in the lengthwise direction and spaced apart from each other in a direction perpendicular to the lengthwise direction, said connecting unit further including a slidable module that is detachably and slidably mounted to said outer guiding flanges and that has said movable electrode set.

3. The displaying device as claimed in claim 2, wherein:
said slidable module of said connecting unit includes a housing that permits said display unit to be rotatably mounted thereto, amounting seat that is disposed in said housing, and a slidable circuit board, which is disposed on said mounting seat and on which said movable electrode set is disposed, said housing being con figured with at least two hooks each detachably and slidably engaging a respective one of said outer guiding flanges.

4. The displaying device as claimed in claim 3, wherein:
said rail has a connecting wall, two side walls extending downwardly and respectively from two opposite sides of said connecting wall, two spaced-apart mounting walls located between said side walls, respectively extending from intermediate portions of said side walls toward each other, and two spaced-apart inner guiding flanges each extending downwardly from an end of a respective one of said mounting walls which is distal from a corresponding one of said side walls; and
said outer guiding flanges respectively extend from bottom ends of said side walls toward said inner guiding flanges, are spaced apart from said inner guiding flanges, and each cooperates with the corresponding one of said side walls and the respective one of said mounting walls to define a guiding groove thereamong, said guiding groove having a lower opening through which a corresponding one of said hooks of said housing is inserted thereinto.

5. The displaying device as claimed in claim 4, wherein:
said housing includes
a tubular wall located at a bottom end of said housing, surrounding a first axis perpendicular to said rail, and defining a through hole, and
a limiting protrusion extending downwardly from a bottom end of said tubular wall; and
said connecting unit further includes a rotatable module interconnecting said slidable module and said display unit, said rotatable module including
a rotatable shaft inserted into said tubular wall through said through hole and rotatable about the first axis, and
a protruding block extending outwardly from an outer surface of said rotatable shaft and co-rotatable with said rotatable shaft to contact said limiting protrusion so as to limit rotation of said rotatable shaft.

6. The displaying device as claimed in claim 5, wherein said display unit has a pivot portion, said rotatable shaft of said rotatable module including a tubular portion that is partially inserted into said through hole of said housing, and a pivot portion that permits said pivot portion of said display unit to be pivotally connected thereto, such that said display unit is pivotable relative to said pivot portion of said rotatable shaft about a second axis that is perpendicular to the first axis.

7. The displaying device as claimed in claim 6, wherein said tubular portion has an outer surface formed with an annular groove, and said rotatable module further includes a C-shaped retaining ring engaging said annular groove of said tubular portion and abutting against a top end of said tubular wall of said housing for preventing removal of said tubular portion from said through hole.

8. The displaying device as claimed in claim 6, wherein said rotatable module further includes an O-ring sleeved on said tubular portion of said rotatable shaft and in frictional contact with an inner surface of said tubular wall.

9. The displaying device as claimed in claim 4, wherein said connecting unit further includes a retaining module having at least two retaining pieces each of which is removably inserted into said lower opening of said guiding groove defined among a respective one of said outer guiding flanges, a corresponding one of said side walls and the respective one of said mounting walls, and blocks the corresponding one of said hooks in the lengthwise direction so as to prevent movement of said housing of said slidable module relative to said rail.

10. The displaying device as claimed in claim 9, wherein each of said retaining pieces has an insert portion inserted into a corresponding one of said lower openings, and a hold portion protruding out of the corresponding one of said lower openings.

11. The displaying device as claimed in claim 1, wherein said fixed electrode set includes two spaced-apart fixed electrodes extending in the lengthwise direction, said movable electrode set of said slidable module including at least two spaced-apart movable electrodes in sliding contact with said fixed electrodes, respectively.

12. The displaying device as claimed in claim 1, wherein said fixed circuit board includes a board body, and a partition disposed on said board body and between said fixed electrodes for separating said fixed electrodes.

13. The displaying device as claimed in claim 3, wherein:
said rail has two side walls, a connecting wall interconnecting said side walls, and two inner guiding flanges extending in the lengthwise direction, and extending respectively from bottom ends of said side walls toward each other for placement of said fixed circuit board thereon; and
each of said outer guiding flanges extends from the bottom end of a respective one of said side walls away from said inner guiding flanges.

14. The displaying device as claimed in claim 13, wherein:
said housing of said slidable module has a bottom surface formed with a through hole;
said mounting seat has a limiting protrusion; and
said connecting unit further includes a rotatable module interconnecting said slidable module and said display unit, said rotatable module including
a rotatable shaft that is inserted into said through hole and that is rotatable about a first axis perpendicular to said rail, and
a retaining ring that is disposed under said mounting seat, that is co-rotatably connected to a top end of said rotatable shaft, and that has a protruding portion extending upwardly toward said mounting seat and rotatable to contact said limiting protrusion so as to limit rotation of said rotatable shaft.

15. The displaying device as claimed in claim 13, wherein each of said side walls of said rail cooperates with a respective one of said outer guiding flanges to define a guiding groove that extends in the lengthwise direction and that detachably and slidably engages a corresponding one of said hooks of said housing.

16. The displaying device as claimed in claim 15, wherein said connecting unit further includes a retaining module having at least two retaining pieces each of which is removably inserted into said guiding groove defined among a respective one of said side walls and the respective one of said outer guiding flanges, and that blocks the corresponding one of said hooks in the lengthwise direction so as to prevent movement of said housing of said slidable module relative to said rail.

17. The displaying device as claimed in claim 16, wherein each of said retaining pieces has an insert portion inserted into a corresponding one of said guiding grooves, and a hold portion protruding out of the corresponding one of said guiding grooves.

18. The displaying device as claimed in claim 15, wherein said housing has an inner surface formed with a retaining groove that slidably engaging one of said outer guiding flanges.

19. The displaying device as claimed in claim 18, wherein said one of said outer guiding flanges has a width greater than that of the other one of said outer guiding flanges in the direction perpendicular to the lengthwise direction.
